(19) United States
(12) Patent Application Publication
(10) Pub. No.: US 2012/0299177 A1
(43) Pub. Date: Nov. 29, 2012

(54) SEMICONDUCTOR COMPONENT AND METHOD OF FABRICATING THE SAME

(75) Inventors: Chun Chieh Chao, Tantzu (TW); Chun Hung Lu, Taichung Hsien (TW)

(73) Assignee: Siliconware Precision Industries Co., Ltd., Taichung Hsien (TW)

(21) Appl. No.: 13/242,359

(22) Filed: Sep. 23, 2011

(30) Foreign Application Priority Data
May 24, 2011 (TW) 100118060

(51) Int. Cl. H01L 23/48; H01L 21/60

(52) U.S. Cl. 257/737; 438/613; 257/E23.021; 257/E21.506

(57) ABSTRACT

A semiconductor component structure is provided, which includes a body formed with openings, an insulating layer formed on surfaces of the body and the openings, conductive bumps formed in the openings, and a re-distributed circuit formed by conductive traces electrically connecting the conductive bumps, wherein the conductive traces are formed on a portion of the insulating layer on the body. As the conductive traces and the conductive bumps are formed on and in the body prior to the formation of the re-distributed circuit. The process for fabricating the semiconductor component structure is simplified and the reliability of the semiconductor component structure is enhanced. A method for fabricating the semiconductor component is also provided.

### FIELD OF THE INVENTION

The present invention relates to semiconductor component structures and fabrication methods thereof, and, more particularly, to a semiconductor component structure for a semiconductor package and a method for fabricating the same.

### BACKGROUND OF THE INVENTION

With the rapid development of science and technology, a variety of new products is developed continuously in order to meet the consumer needs with the demands of easy to use and easy to carry. Nowadays, all types of electronic products are trending light, thin, short, and small.

Although, at the present time, a variety of electronic products is trending light, thin, short, and small, these electronic products are still desired to have high-performance, low-power-consumption, and multi-function characteristics. Therefore, the industry gradually develops flip-chip semiconductor packages. The flip-chip semiconductor packages dispose the active surface of a semiconductor chip to face down, for a plurality of solder bumps to be implanted on the electrode pads formed on the active surface so as for the semiconductor chip to be electrically connected to a substrate via the solder bumps. A gap between the semiconductor chip and the substrate is thus formed and required to be filled with an underfill material. Compared with the conventional semiconductor package employing bonding wires to electrically connect a semiconductor chip to a substrate for the semiconductor chip to be mounted thereon, the flip-chip package semiconductor has high-performance, thin, and small characteristics.

However, when the semiconductor chip is scaling down, the aforementioned flip chip semiconductor package can not meet the requirement therefor. The reason is that when the semiconductor chip is continuously microminiaturizing and has high efficiency, the area of the semiconductor chip is also gradually reduced. In addition, the active surface of the semiconductor chip still needs to accommodate more electrode pads, and the area of the electrode pads is also relatively reduced. When the semiconductor chip is coupled to the substrate with solder bumps, the miniaturized solder bumps tend to be cracked or broken, due to the difference in the coefficient of thermal expansion (CTE) between the semiconductor chip, underfills, solder bumps, package substrate materials is too large. As a result, the electrical reliability of the flip-chip semiconductor chip is poor.

Hereupon, the industry has then developed another type of package structures to cope with the aforementioned issue. This type of package structure employs a silicon carrier board for a semiconductor chip to be mounted thereon and electrically connecting the semiconductor chip to a substrate via the silicon carrier board. As the semiconductor chip is indirectly electrically connected to the substrate and the CTE of the semiconductor chip is close to that of the silicon carrier board, the issue of the solder bump cracking or breaking can be eliminated. Wherein, the silicon carrier board has to form a plurality of silicon through-silicon vias (TSVs), and the TSVs need to be filled with a conductive material in order to electrically connect the semiconductor chip via the TSVs.

FIG. 1 is a cross-sectional view of a package structure employing a conventional TSV silicon carrier board. Referring to FIG. 1, a substrate 10 is electrically coupled to TSVs 120 of a silicon carrier board 12 via solder balls 11, while the TSVs 120 are filled with a metal material. Further, a semiconductor chip 13 is disposed on the silicon carrier board 12 to form a package structure that has the silicon carrier board 12 interposed between the substrate 10 and the semiconductor chip 13.

The method of filling the TSVs with a metal material has been disclosed by for instance, U.S. Pat. No. 7,638,867. The TSVs are filled with a solder material by a stencil printing method. When the radius of the TSV is getting smaller, the TSV can not be completely filled with the metal material. Accordingly, it will generate cavities in the metal material filled in the TSVs, thereby leading to poor reliability of the electrical connection of the TSVs. Moreover, if the TSVs fail to be filled with the metal material, electronic components, such as the semiconductor chip and substrate, on the top and bottom surfaces of the TSV carrier board can not be electrically connected.

Therefore, in view of the above problems, a simplified process for fabricating the semiconductor component structure for the purpose of increasing the overall packaging process efficiency and reducing the manufacturing cost have become very important in order to overcome the problems encountered in known semiconductor technology.

### SUMMARY OF THE INVENTION

In view of the problems encountered in known technology, an object of this invention is to provide a semiconductor component structure, comprising: a body having a plurality of openings; an insulating layer formed on the body and in the openings; and a re-distributed circuit comprising a plurality of conductive bumps formed in the openings and conductive traces electrically connected to the conductive bumps, wherein the conductive traces are formed on a portion of the insulating layer on the body.

According to the above semiconductor component structure, the conductive bumps are flush with the conductive trace.

According to the above description, the present invention further comprises a first insulating protective layer formed on the insulating layer and the re-distributed circuit, and having a plurality of first insulating protective layer openings to expose a portion of the re-distributed circuit for a plurality of contact pads.

As mentioned above, the present invention further comprises a metal protective layer formed on the exposed portion of the re-distributed circuit.

In order to obtain the aforementioned semiconductor component structure, the present invention provides a method for fabricating the semiconductor component structure, comprising: providing a body having a plurality of openings; forming an insulating layer on the body and in the openings; forming a conductive layer on the insulating layer; forming a conductive bump on the conductive layer in each of the openings, wherein each of the conductive bumps is flush with the conductive layer on the body; forming a patterned wiring photoresist layer on the conductive bumps and a portion of the conductive layer; etching and removing another portion of the conductive layer exposed from the patterned wiring photoresist layer so as to expose the insulating layer and allow the portion of the conductive layer covered by the pattern wiring photoresist layer to form into conductive traces; and removing the patterned wiring photoresist layer for forming a re-distributed circuit including the conductive bumps and the conductive traces.

According to the above method for fabricating the semiconductor component structure, further comprising a first insulating protective layer formed on the insulating layer in the opening and the re-distributed circuit, and having a plurality of first insulating protective layer openings to expose a portion of the re-distributed circuit for a plurality of contact pads. A metal protective layer is formed on each of the contact pads.

According to the above method for fabricating the semiconductor component structure, the material of the body is silicon.

From the foregoing, a semiconductor component structure and a fabrication method of the present invention have a body with a plurality of openings first forming an insulating layer, a conductive layer and a conductive bump, then forming a re-distributed circuit from the patterned conductive layer, wherein the TSVs can not be completely filled with the metal material of known technology to form the conductive bump. It will generate cavities of the TSVs filled with the metal material. Therefore, it leads to the problem of poor reliability. Moreover, the TSVs can not be filled with the metal material, and thus forming an open circuit. Therefore, the present invention provides a semiconductor component structure and a fabrication method for simplifying the overall process, reducing the material cost, and also increasing reliability of the product structure.

### BRIEF DESCRIPTION OF THE DRAWINGS

FIG. 1 illustrates a cross-sectional view of a stacking package structure of known through-silicon via (TSV) chip; and

FIGS. 2A-2F illustrate cross-sectional views of a method for fabricating the semiconductor component structure in accordance with an embodiment of the present invention; wherein FIG. 2A′ illustrates another embodiment of FIG. 2A; FIG. 2D′ illustrates a schematic drawing of the built-up structure disposed on re-distributed circuits; FIG. 2F′ illustrates a semiconductor component structure in accordance with FIG. 2A′.

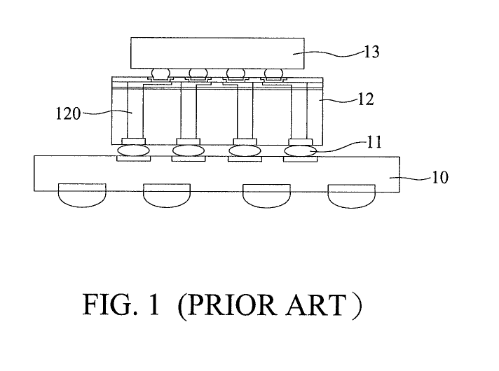

### DETAILED DESCRIPTION OF THE INVENTION

The following embodiments are provided to illustrate the disclosure of the present invention. These and other advantages and effects can be apparent to one ordinarily skilled in the art after reading the disclosure of this specification.

Please notice the figures of this specification show that the structure, ratio, size, etc. are revealed only to associate with the contents of this specification for understanding and reading of one skilled in the art. The description should not be deemed to be a limitation on the scope of the invention, and thus not having the technical meaning. Accordingly, any structure modification, change of ratio or size adjustment may occur to one skilled in the art without departing from the effectiveness, objective and scope of the claimed inventive concept. In the meanwhile, this specification uses some terms, such as “top”, “bottom”, “one”, “up”, and “down” only for a clear description, rather than limits the scope of the present invention. Consequently, various modifications and adaptations may occur to one skilled in the art without departing from the technical content and scope of the claimed inventive concept.

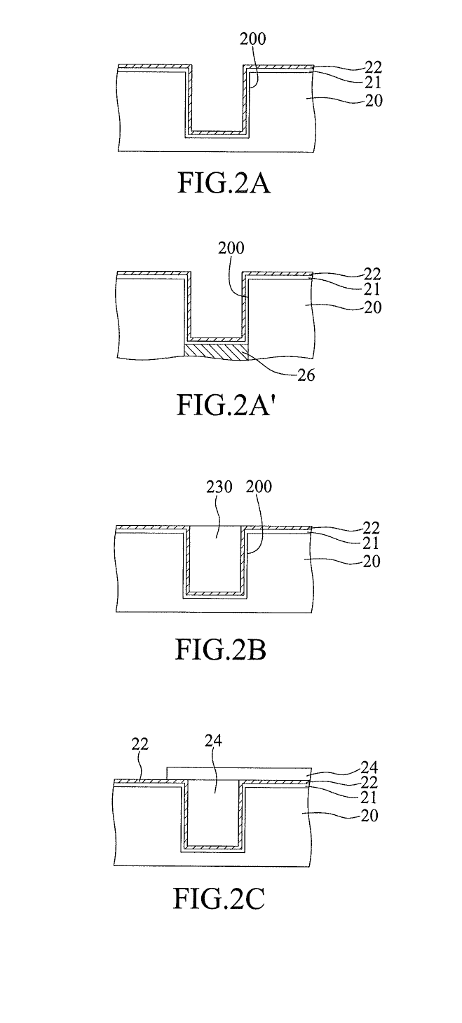

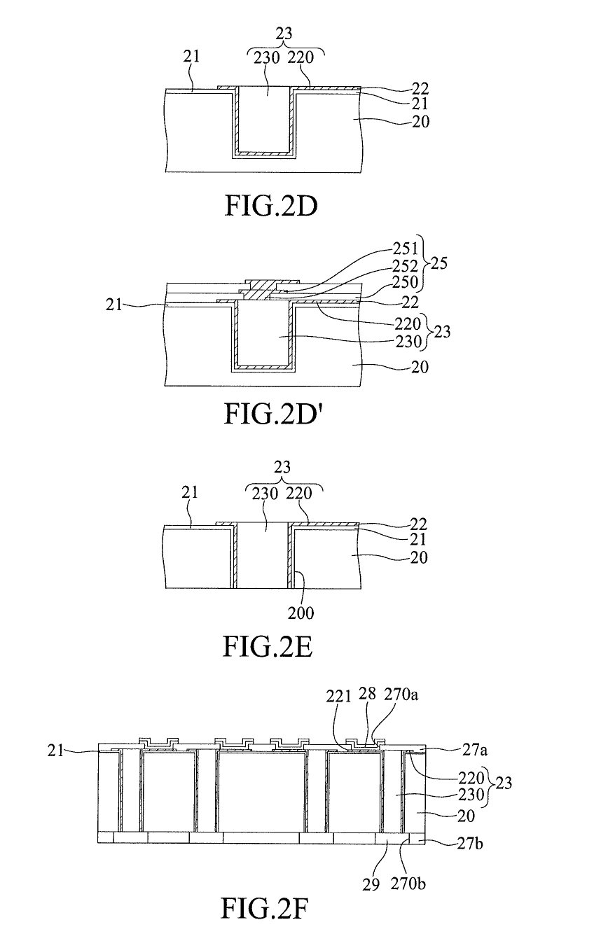

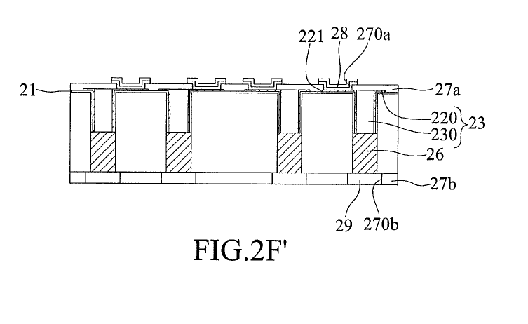

FIGS. 2A-2F illustrate cross-sectional views of a method for fabricating the semiconductor component structure according to the present invention.

As shown in FIG. 2A, firstly, the present invention provides a body 20 with a plurality of openings 200, wherein the material of the body 20 is, for example, a silicon material. It can be applied to an interlayer plate of a multi-chip stack structure, but not limited to this application. In addition, FIG. 2A′ illustrates another embodiment of FIG. 2A. The bottom of the openings 200 is connected to the surface of conductive through vias 26. An insulating layer 21 and a conductive layer 22 are formed in turn on the surface of the body 20 and the surface of the openings.

As shown in FIG. 2B, the conductive layer 22 is used as an electroplated current conductive path. The conductive layer 22 of the opening 200 is electroplated to form a conductive bump 230, and the conductive bump 230 is flush with the conductive layer 22 above the surface of the body 20.

As shown in FIG. 2C, a patterned wiring photoresist layer 24 is formed on the conductive bump 230 and a portion of the conductive layer 22 covered by the patterned wiring photoresist layer 24 to form into conductive traces 220. A re-distributed circuit pattern is formed by the patterned wiring photoresist layer 24, and an exposed portion of conductive layer 22 is exposed by the patterned wiring photoresist layer 24. A photoresist layer is fully disposed on the conductive bump 230 and the conductive layer 22. The patterned wiring photoresist layer 24 is formed on the photoresist layer via the patterned process; subsequently, the photoresist layer is formed on the conductive layer 22 of the conductive trace.

As shown in FIG. 2D, a portion of the conductive layer 22 of the exposed patterned photoresist layer 24 is first etched and removed to expose an insulating layer 21, and a conductive trace 220 is formed and is the portion of the conductive layer 22 on which the patterned wiring photoresist layer 24 is formed. After that, the patterned wiring photoresist layer 24 is removed to expose the conductive trace 220. The re-distributed circuit 23 is formed and includes the conductive bump 230 and the conductive trace 220. Besides, at least one built-up structure 25 is formed on the re-distributed circuit 23. The built-up structure 25 comprises at least one dielectric layer 250, a wiring layer 251 disposed on the dielectric layer 250, and a conductive blind via 252 disposed in the dielectric layer 250 and electrically connected to the wiring layer 251 and the re-distributed circuit 23, as shown in FIG. 2D′.

As shown in FIG. 2E, subsequently, the bottom of the body 20 is removed to grind and etch the insulating layer 21 and the surface of conductive layer 22. A conductive bump 230 is exposed below the opening 200. In this embodiment, the conductive bump 230 is used as a conductive path of the top and bottom surfaces of the body 20.

As shown in FIG. 2F, a first insulating protective layer 27a having a plurality of first insulating protective layer openings 270a is formed on the insulating layer 21 and the re-distributed circuit 23, and a portion of the re-distributed circuit 23 is also exposed on the first insulating protective layer opening 270a. The exposed re-distributed circuit 23 is used as a contact pad 221, and thus a metal protective layer 28 formed on the contact pads 221, such as an under bump metallization (UBM) layer. On the other hand, the re-distributed circuit 23 and the metal protective layer 28 can be formed on the built-up structure 25.

In addition, a second insulating protective layer 27b having a plurality of second insulating protective layer openings 270b is formed on the bottom surface of the body 20, and the bottom surface of the conductive bump 230 is also exposed by the openings of the second insulating layer 270b. A bump pad 29 is formed on each of the openings 270b of the second insulating protective layer to electrically connect each of the conductive through vias 26 to each of the bump pads 29. Further, the bottom surface of body 20 is flush with the relative surface of body 20 in order to form an built-up structure on the bottom surface of body 20 and the surface of conductive bump 230 (not shown). Afterwards, a second insulating protective layer 27b and a bump pad 29 are formed.

Referring now to FIG. 2F′, in another embodiment, if the bottom of the opening 200 of body 20 is connected to the conductive through via 26, as shown in FIG. 2A′, each of conductive through vias 26 is exposed on the second insulating protective layer openings 270b. A bump pad 29 is formed on the conductive through via 26 of the second insulating protective layer opening 270b.

The present invention provides a semiconductor component structure, comprising: a body 20, an insulating layer 21 and a re-distributed circuit 23.

Said body 20 has a plurality of openings 200, and the material of the body 20 contains a silicon material, for example.

Said insulating layer 21 is formed on the surface of the body 20 and the surface of the openings 200.

Said re-distributed circuit 23 is formed by the conductive bump 230 in the openings 200, and the conductive trace 220 is connected to conductive bump 230, wherein a portion of the insulating layer 21 is formed from the conductive trace 220, and the conductive trace 220 is further formed between the insulating layer 21 of the openings 200 and the conductive bump 230. In addition, the conductive bump 230 is flush with the conductive trace 220 above the surface of the body 20.

Moreover, the semiconductor component structure further comprises a first insulating protective layer 27a formed from the insulating layer 21 of the body 20 surface and the re-distributed circuit 23, and having a plurality of first insulating protective layer openings 270a to expose a portion of the re-distributed circuit 23 for a plurality of contact pads 221.

The present invention provides a semiconductor component structure and a method for fabricating the same. An insulating layer and a conductive layer are formed from a body with a plurality of openings, and then a conductive bump is formed from the opening. The formed conductive bump is flush with the conductive layer of the body. Afterwards, a patterned wiring photoresist layer is formed on the conductive layer. Subsequently, the conductive layer uncovered by the patterned wiring photoresist layer is etched and removed to form a conductive trace on a portion of the conductive layer. Subsequently, the patterned wiring photoresist layer is removed. A re-distributed circuit is formed from the conductive bump and the conductive trace. In the method and the semiconductor component structure according to the present invention, due to the conductive bump formed by the electroplated method, the TSV can not be completely filled with a metal material of known technology to form the conductive bump. It will generate cavities with a metal material. Therefore, it leads to the problem of poor reliability.

Moreover, the TSV can not be filled with a metal material, and thus forming an open circuit. Therefore, the present invention provides a semiconductor component structure and a method for fabricating the same for simplifying the overall process, reducing the material cost, and also increasing reliability of the product structure.

The above descriptions of the embodiments are only to illustrate the preferred implementation according to the present invention, and it is not to limit the scope of the present invention. Accordingly, all modifications and variations completed by those with one skilled in the art should fall within the scope of the present invention defined via the appended claims. Therefore, the claims of the present invention are described as follows.

1. A semiconductor component structure, comprising:
a body having a plurality of openings;
an insulating layer formed on the body and in the openings; and
a re-distributed circuit comprising a plurality of conductive bumps formed in the openings and conductive traces electrically connected to the conductive bumps, wherein the conductive traces are formed on a portion of the insulating layer on the body surface.

2. The semiconductor component structure of claim 1, wherein the body is made of a silicon material.

3. The semiconductor component structure of claim 1, wherein the conductive bumps are flush with the conductive traces.

4. The semiconductor component structure of claim 1, wherein the conductive traces each further extend into the opening at a position between the insulating layer and the conductive bump in the opening.

5. The semiconductor component structure of claim 1, further comprising at least one built-up structure formed on the re-distributed circuit.

6. The semiconductor component structure of claim 1, further comprising a first insulating protective layer formed on the insulating layer and the re-distributed circuit, and having a plurality of first insulating protective layer openings to expose a portion of the re-distributed circuit.

7. The semiconductor component structure of claim 6, further comprising a metal protective layer formed on the exposed portion of the re-distributed circuit.

8. A method for fabricating a semiconductor component structure, comprising:
providing a body having a plurality of openings;
forming an insulating layer on the body and in the openings;
forming a conductive layer on the insulating layer;
forming a conductive bump on the conductive layer in each of the openings, wherein each of the conductive bumps is flush with the conductive layer on the body;
forming a patterned wiring photoresist layer on the conductive bumps and a portion of the conductive layer;
etching and removing another portion of the conductive layer exposed from the patterned wiring photoresist layer, so as to expose the insulating layer and allow the portion of the conductive layer covered by the patterned wiring photoresist layer to form into conductive traces; and
removing the patterned wiring photoresist layer for forming a re-distributed circuit including the conductive bumps and the conductive traces.

9. The method of claim 8, wherein the body is made of silicon material.

10. The method of claim 8, further comprising forming at least one built-up structure on the re-distributed circuit.

11. The method of claim 8, further comprising forming a first insulating protective layer on the insulating layer in the opening and the re-distributed circuit, wherein the first insulating protective layer has a plurality of first insulating protective layer openings to expose a portion of the re-distributed circuit.

12. The method of claim 11, further comprising forming a metal protective layer on the exposed portion of the re-distributed circuit.
